(19) United States
(12) Patent Application Publication
(10) Pub. No.: US 2022/0217865 A1
(43) Pub. Date: Jul. 7, 2022

(54) CIRCUIT STRUCTURE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Yuki FUJIMURA, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/606,558

(22) PCT Filed: Apr. 22, 2020
(86) PCT No.: PCT/JP2020/017321

§ 371 Date: Oct. 26, 2021

(30) Foreign Application Priority Data
May 7, 2019 (JP) 2019-087546

(51) Int. Cl. H05K 7/20

(52) U.S. Cl. CPC H05K 7/2039

(57) ABSTRACT

A circuit structure of the present disclosure includes: a heat-generating member; at least one connection conductor; at least one insulative heat transfer member; and an insulative base member. The heat-generating member generates heat as a result of being energized, the connection conductor is connected to the heat-generating member in a heat-transferable state, the heat transfer member is formed in the shape of a heat-transferable sheet, the base member includes a base main body and a positioning portion, the base main body, together with the connection conductor, sandwiches the heat transfer member, and the positioning portion is formed so as to protrude from the base main body, and positions the connection conductor relative to the base main body as a result of coming into contact with the connection conductor.

### TECHNICAL FIELD

The present disclosure relates to a circuit structure.

### BACKGROUND ART

For example, a circuit structure including a metal battery case that houses a relay therein is disclosed in JP 2018-93711A. This circuit structure includes a relay, a first bus bar connected to the relay, a heat conduction sheet arranged between the relay and the first bus bar, and a heat conduction sheet arranged between the first bus bar and the battery case. The heat conduction sheets are each sandwiched between the first bus bar and the relay or between the first bus bar and the battery case, whereby the efficiency with which the relay is cooled is improved due to heat from the relay being transferred from the relay to the first bus bar and from the first bus bar to the battery case.

### CITATION LIST

### Patent Documents

Patent Document 1: JP 2018-93711A

### SUMMARY OF INVENTION

### Technical Problem

Incidentally, heat conduction sheets of this type can be in contact with members in a state in which the adhesion therebetween is high and enhance heat conduction efficiency by being sandwiched between the members and being appropriately compressed.

However, there are cases in which a heat conduction sheet is excessively compressed due to the manufacturing tolerance of members forming a circuit structure or the assembly tolerance when the members are attached to each other. If a heat conduction sheet is excessively compressed, there is a concern that members may be damaged as a result of high stress being applied to portions where the members are connected to one another due to the resilience of the heat conduction sheet.

The present specification discloses a technique for preventing stress from being applied to members while improving cooling efficiency.

### Solution to Problem

A circuit structure according to the present disclosure is a circuit structure including: a heat-generating member; at least one connection conductor; at least one insulative heat transfer member; and an insulative base member, wherein the heat-generating member generates heat as a result of being energized, the connection conductor is connected to the heat-generating member in a heat-transferable state, the heat transfer member is formed in the shape of a heat-transferable sheet, the base member includes a base main body and a positioning portion, the base main body, together with the connection conductor, sandwiches the heat transfer member, and the positioning portion is formed so as to protrude from the base main body, and positions the connection conductor relative to the base main body as a result of coming into contact with the connection conductor.

### Advantageous Effects of Invention

According to the present disclosure, the application of stress to members can be suppressed while improving cooling efficiency.

### BRIEF DESCRIPTION OF DRAWINGS

FIG. 1 is an exploded perspective view of a circuit structure pertaining to an embodiment.

FIG. 2 is a perspective view of the circuit structure.

FIG. 3 is a partial plan view of the circuit structure.

FIG. 4 is a cross-sectional view taken along line A-A in FIG. 3.

FIG. 5 is a cross-sectional view taken along line B-B in FIG. 3.

FIG. 6 is a perspective view of a base member.

FIG. 7 is a perspective view in which first heat transfer sheets have been attached to the base member.

FIG. 8 is a perspective view in which connection conductors have been attached to the base member.

FIG. 9 is a perspective view in which a relay has been attached to the base member.

### DESCRIPTION OF EMBODIMENT

### Description of Embodiments of Present Disclosure

First, embodiments of the present disclosure will be listed and described.

(1) A circuit structure including: a heat-generating member; at least one connection conductor; at least one insulative heat transfer member; and an insulative base member, wherein the heat-generating member generates heat by being energized, the connection conductor is connected to the heat-generating member in a heat-transferable state, the heat transfer member is formed in the shape of a heat-transferable sheet, the base member includes a base main body and a positioning portion, the base main body, together with the connection conductor, sandwiches the heat transfer member, and the positioning portion is formed so as to protrude from the base main body, and positions the connection conductor relative to the base main body as a result of coming into contact with the connection conductor.

Due to the connection conductor coming into contact with the positioning portion, the gap between the connection conductor and the base member can be prevented from becoming less than or equal to a predetermined dimension. That is, the connection conductor and the base main body can be brought in contact with the heat transfer member while preventing the heat transfer member sandwiched between the base main body and the connection conductor from being excessively compressed. Thus, the efficiency with which the heat-generating member is cooled can be improved due to the heat from the heat-generating member being transferred from the heat-generating member to the connection conductor and from the connection conductor to the base member. Furthermore, since the heat transfer member is not excessively compressed by the connection conductor, stress originating from the resilience of the heat transfer member can be prevented from being applied to the members and the members can be prevented from being damaged.

(2) The positioning portion is arranged in the outer periphery of the heat transfer member. The positioning portion can also be used as a guide for attaching the heat transfer member to the base main body.

(3) The connection conductor includes a member connection portion and an extending portion, the member connection portion can be connected to the heat-generating member, the extending portion extends in the shape of a plate from the member connection portion, and the positioning portion is formed so as to be capable of coming into contact with the entire outer peripheral edge portion of the extending portion.

Since the positioning portion comes into contact with the entire outer peripheral edge portion of the extending portion, the connection conductor can be more reliably positioned by the positioning portion compared to a case in which the positioning portion comes into contact with one end of the extending portion, for example. Thus, the heat transfer member can be reliably prevented from being excessively compressed by the connection conductor.

(4) The heat transfer member is formed so as to be elastically compressible, and the protruding length of the positioning portion from the base main body is set to be equal to the thickness of the heat transfer member when compressed by a predetermined amount. Here, the term “equal” is used to include both a case in which the protruding length of the positioning portion from the base main body and the thickness of the heat transfer member when compressed by the predetermined amount are equal and a case in which, even if the two dimensions are not equal, the two dimensions can be regarded as being substantially equal.

The heat transfer member can be prevented from being excessively compressed by the predetermined amount or more when the connection conductor is pressed toward the base main body.

(5) The base member further includes a plurality of locking portions, and the plurality of locking portions lock, from the side opposite from the heat transfer member, the connection conductor compressing the heat transfer member.

Due to the retaining portions locking, from the side opposite from the heat transfer member, the connection conductor compressing the heat transfer member, the heat transfer member can be kept in a state in which the heat transfer member is compressed by the predetermined amount by the connection conductor and the base main body. Thus, a state in which the heat transfer member is brought in close contact with the connection conductor and the base main body in an appropriate manner can be maintained, and the heat transfer efficiency of the heat transfer member can be improved.

(6) The heat-generating member and the connection conductor are connected in a heat-transferable state by a fastening member, the connection conductor has an insertion hole into which a shaft portion of the fastening member is inserted, and the insertion hole is formed so as to be elongated in the direction in which the connection conductor comes into contact with the positioning portion.

The shaft portion of the fastening member can move inside the insertion hole in the direction in which the connection conductor comes into contact with the positioning portion. That is, the assembly tolerance occurring between the heat-generating member, the connection conductor, and the positioning portion can be absorbed by the insertion hole. Thus, stress originating from the assembly tolerance can be prevented from being applied to the members and the members can be prevented from being damaged.

(7) A metal bracket and at least one second heat transfer member are further included, the base member is fixed to the bracket, the second heat transfer member is formed in the shape of a heat-transferable sheet and sandwiched between the base main body and the bracket, the base main body further includes a second positioning portion, and the second positioning portion is formed so as to protrude toward the bracket side from the base main body, and positions the bracket relative to the base main body as a result of coming into contact with the bracket.

The heat from the heat-generating member transferred to the base member can be released to the bracket via the second heat transfer member. Furthermore, the second heat transfer member is similar to the heat transfer member in that the gap between the bracket and the base main body can be prevented from becoming less than or equal to a predetermined dimension due to the bracket coming into contact with the second positioning portion. Thus, the second heat transfer member can be prevented from being excessively compressed.

That is, since the second heat transfer member is not excessively compressed by the bracket, stress originating from the resilience of the second heat transfer member can be prevented from being applied to the members and the members can be prevented from being damaged.

### Details of Embodiment of Present Disclosure

A specific example of a circuit structure 10 according to the present disclosure will be described with reference to the drawings below. Note that the present disclosure is not limited to these examples, and is intended to include all modifications that are indicated by the claims and are within the meaning and scope of equivalents of the claims.

### Embodiment

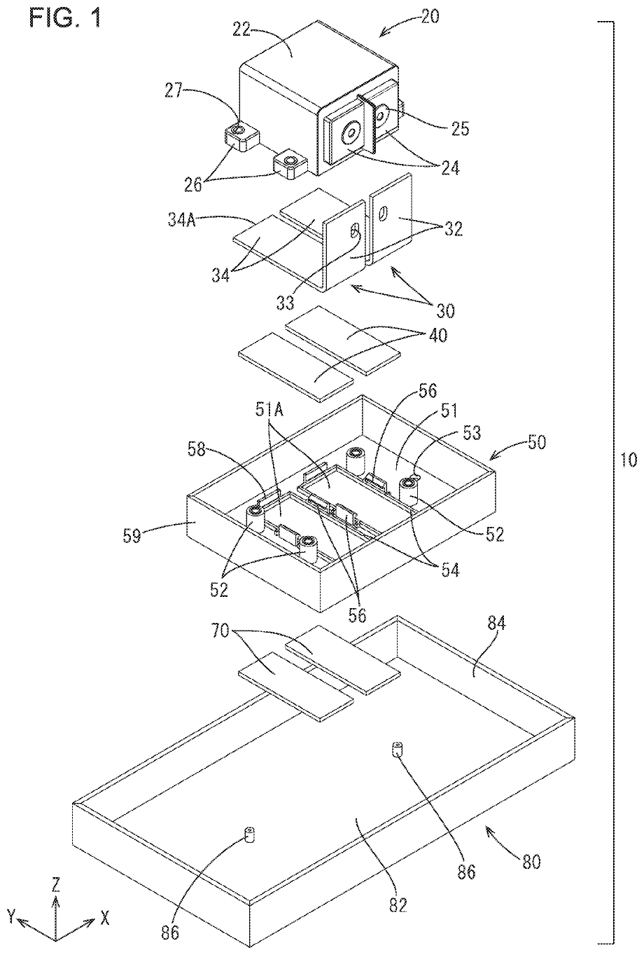

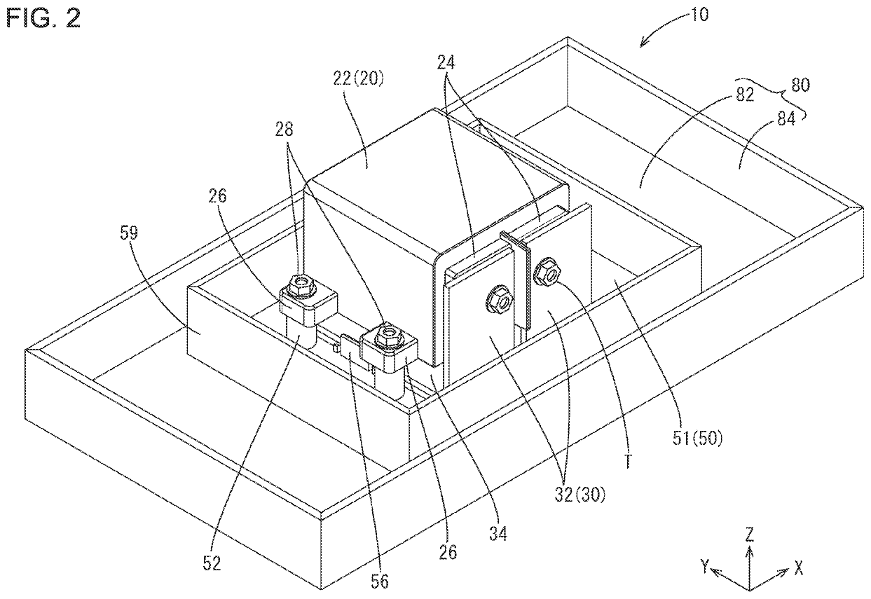

One embodiment of the present disclosure will be described with reference to FIGS. 1 to 9.

### [Circuit Structure 10]

The circuit structure 10 in the present embodiment is attached to a frame of an unillustrated battery pack that is mounted in a vehicle such as an electric automobile or a hybrid automobile, for example, and controls the electric power of the battery pack.

While the circuit structure 10 can be oriented in any direction, in the following description, the direction indicated by arrow Z is regarded as the upward direction, the direction indicated by arrow Y is regarded as the rearward direction, and the direction indicated by the arrow X is regarded as the rightward direction. Furthermore, when more than one of the same member is provided, the reference symbol therefor may be provided to only some of the members and may be omitted for the rest.

As illustrated in FIG. 1, the circuit structure 10 includes a relay (one example of a “heat-generating component”) 20, a pair of connection conductors 30, a pair of first heat transfer sheets (one example of the “heat transfer member”) 40, a base member 50, a pair of second heat transfer sheets (one example of the “second heat transfer member”) 70, and a bracket 80.

### [Relay 20]

The relay 20 is a mechanical relay and includes a rectangular solid-shaped relay main body 22, a pair of terminal portions 24, and a plurality of fixing portions 26, as illustrated in FIGS. 1 to 3.

The relay main body 22 has an unillustrated contact portion and coil portion therein. On the front surface of the relay main body 22, the pair of terminal portions 24 are arranged side by side in the left-right direction.

When a current is applied between the pair of terminal portions 24 via the contact portion of the relay main body 22, heat generated by the contact portion is transferred to the pair of terminal portions 24 and the pair of terminal portions 24 emit heat. The terminal portions 24 each have a bolt hole 25 that extends rearward.

The plurality of fixing portions 26 are formed so as to protrude in the shape of plates. Two fixing portions 26 are formed on each of the two side surfaces on the two sides of the relay main body 22 in the left-right direction. The fixing portions 26 have insertion holes 27 penetrating the fixing portions 26 in the top-bottom direction. The relay 20 is fixed to the base member 50 as a result of bolts 28 being inserted into the insertion holes 27 and the bolts 28 being fastened to later-described bolt fastening portions 52 of the base member 50.

### [Connection Conductors 30]

The pair of connection conductors 30 are each formed by machining an electroconductive metal plate member. As illustrated in FIGS. 1 to 4, the connection conductors 30 each include a member connection portion 32 and an extending portion 34.

The member connection portions 32 have the shape of rectangular flat plates that extend from the positions of the terminal portions 24 of the relay 20 to below the relay main body 22.

The member connection portions 32 are arranged so as to extend in the top-bottom direction along the front surfaces of the terminal portions 24 of the relay 20. The member connection portions 32 have bolt insertion holes (one example of the “insertion hole”) 33 that penetrate the member connection portions 32 in the front-rear direction, which is the plate thickness direction thereof. The bolt insertion holes 33 are long holes that are elongated in the top-bottom direction, which is the direction in which the relay 20 and the connection conductors 30 are attached to the base member 50. The connection conductors 30 are heat conductively connected to the terminal portions 24 of the relay 20 by inserting shaft portions T1 of bolts T that are fastening members into the bolt insertion holes 33 of the member connection portions 32 and fastening the shaft portions T1 to the bolt holes 25 of the terminal portions 24.

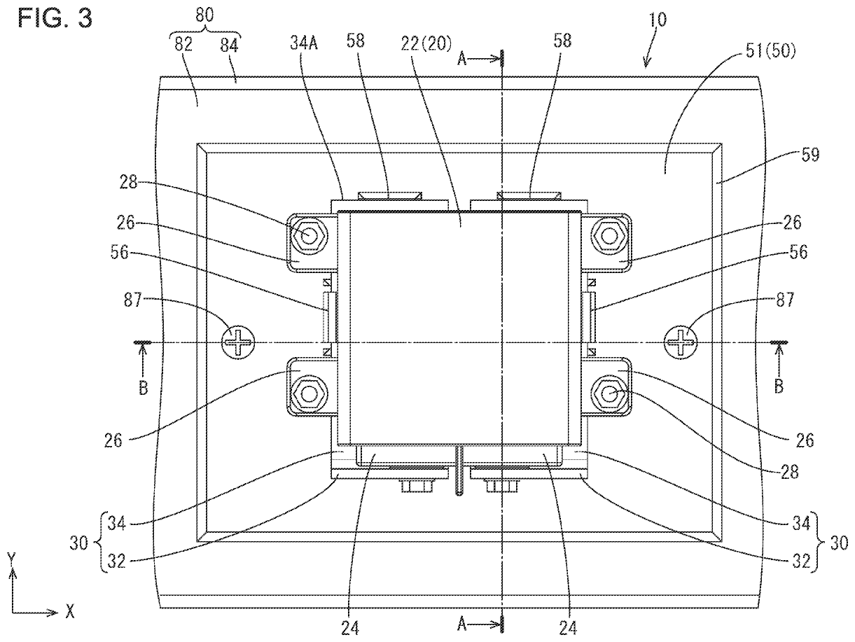

The extending portions 34 are formed in the shape of rectangular plates extending rearward from the bottom edges of the member connection portions 32. The extending portions 34 are arranged below the relay main body 22 in a state in which the outer peripheral edge portions of the extending portions 34 protrude slightly from the projection plane of the relay main body 22, as illustrated in FIG. 3.

Accordingly, when the connection conductors 30 are attached to the relay 20, heat from the terminal portions 24 of the relay 20 is transferred to the extending portions 34 via the member connection portions 32 of the connection conductors 30. The first heat transfer sheets 40 are attached to the bottom surfaces of the extending portions 34, which are on the opposite side from the relay main body 22 side.

### [First Heat Transfer Sheets 40]

The first heat transfer sheets 40 transfer heat from the connection conductors 30 to the base member 50. The first heat transfer sheets 40 are formed in the shape of rectangular sheets that are elongated in the front-rear direction and that are flat with a small thickness in the top-bottom direction using an insulative synthetic resin having greater heat conductivity than air.

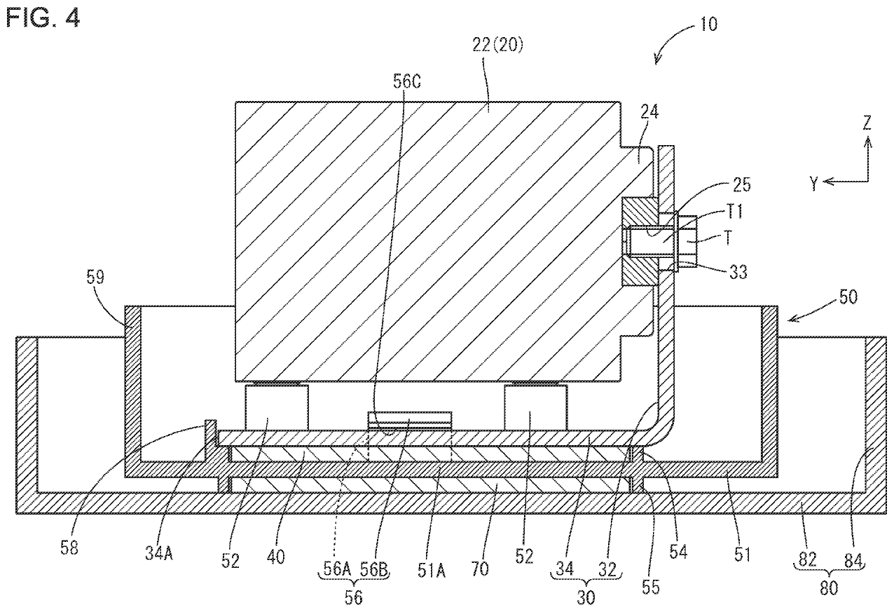

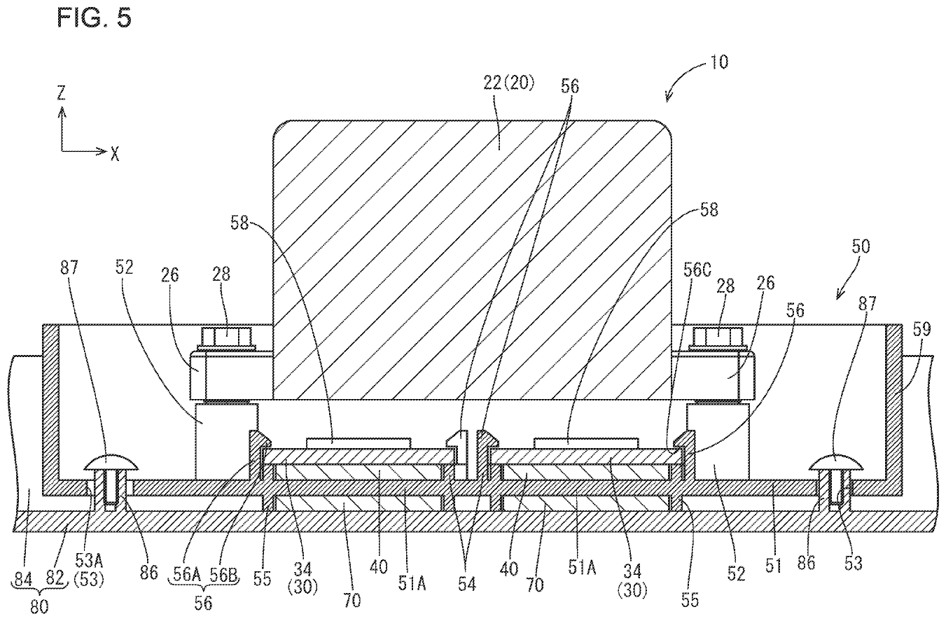

As illustrated in FIGS. 4 and 5, the first heat transfer sheets 40 have unillustrated adhesive layers provided on the two surfaces thereof on both sides in the top-bottom direction, and are affixed to the bottom surfaces of the extending portions 34 of the connection conductors 30 and the top surfaces of later-described mounting portions 51A of the base member 50 using these adhesive layers.

The first heat transfer sheets 40 can be elastically compressed in the top-bottom direction, which is the thickness direction thereof. The first heat transfer sheets 40 are in close contact with the extending portions 34 and the mounting portions 51A due to being compressed by a predetermined amount from both sides in the top-bottom direction by the extending portions 34 and the mounting portions 51A, as illustrated in FIGS. 4 and 5.

### [Base Member 50]

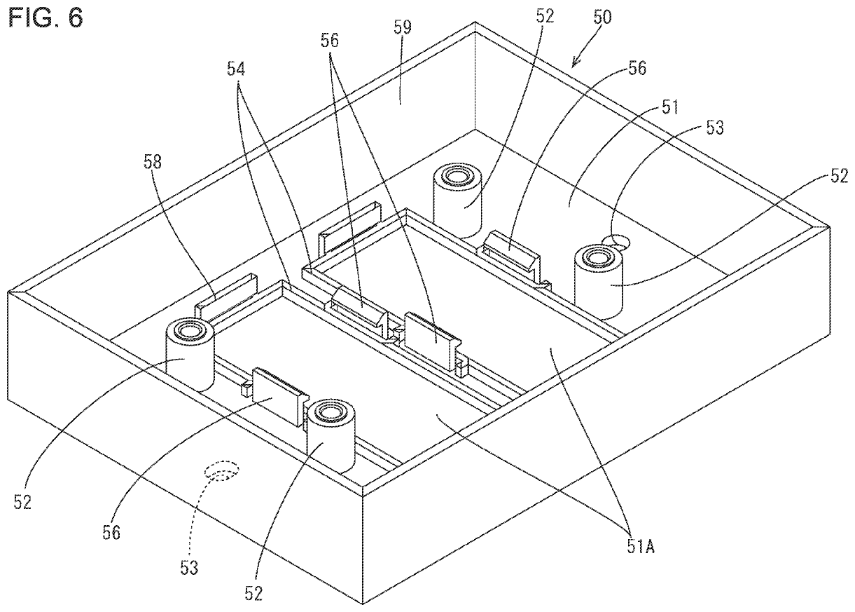

As illustrated in FIGS. 4 and 5, the relay 20, the pair of connection conductors 30, and the first heat transfer sheets 40 are attached to the base member 50 from above, and the second heat transfer sheets 70 and the bracket 80 are attached to the base member 50 from below. The base member 50 is formed using an insulative synthetic resin. As illustrated in FIG. 6, the base member 50 includes a base main body 51, first positioning portions (one example of the “positioning portion”) 54, second positioning portions 55, a plurality of locking portions 56, rear stopping portions 58, and a protective wall 59.

The base main body 51 is formed in the shape of a rectangular flat plate on which the relay 20 and the pair of connection conductors 30 can be arranged.

Two bolt fastening portions 52 extending upward from the base main body 51 are formed on each of the two sides of the base main body 51 in the left-right direction. The relay 20 is fixed to the base member 50 as a result of the fixing portions 26 of the relay 20 being fastened by bolts to these bolt fastening portions 52.

A pair of through holes 53 penetrating the base main body 51 in the top-bottom direction are formed between the regions of the base main body 51 where the bolt fastening portions 52 are arranged and the side edges of the base main body 51 on both sides in the left-right direction.

The base member 50 is fixed to the bracket 80 as a result of later-described screw fastening portions 86 of the bracket 80 being inserted into these through holes 53, as illustrated in FIG. 5, and screws 87 being fastened to the screw fastening portions 86.

As illustrated in FIGS. 5 and 6, a through hole 53A, which is one of the pair of through holes 53, is a long hole that is elongated in the left-right direction. The through hole 53A can absorb the difference in expansion between the base main body 51 and the bracket 80 if the base main body 51 undergoes thermal expansion due to heat from the relay 20.

As illustrated in FIGS. 4 to 6, the center of the base main body 51 is configured as a pair of mounting portions 51A on which the pair of first heat transfer sheets 40 and the later-described pair of second heat transfer sheets 70 are arranged.

The pair of mounting portions 51A are arranged so that they are side by side in the left-right direction. The mounting portions 51A are each formed in the shape of a rectangle that is slightly larger in the front-rear and left-right directions than the first heat transfer sheets 40 and the second heat transfer sheets 70. The pair of first heat transfer sheets 40 are placed on the top surfaces of the pair of mounting portions 51A, and the pair of later-described second heat transfer sheets 70 are arranged on the bottom surfaces of the pair of mounting portions 51A.

In the outer periphery of each mounting portion 51A in the base main body 51, a first positioning portion 54 that protrudes upward from the base main body 51 and a second positioning portion 55 that protrudes downward from the base main body 51 are provided.

As illustrated in FIGS. 4 to 6, the first positioning portions 54 are formed in the shape of continuous rectangular frames that are elongated in the front-rear direction so as to surround the mounting portions 51A continuously over the entire periphery thereof. The long-side length of the first positioning portions 54 is slightly longer than the long-side length of the extending portions 34 of the connection conductors 30, and the short-side length of the first positioning portions 54 is equal to the short-side length of the extending portions 34. Here, the term “equal” is used to include both a case in which the short-side length of the first positioning portions 54 and the short-side length of the extending portions 34 are equal and a case in which, even if the two dimensions are not equal, the two dimensions can be regarded as being substantially equal.

Accordingly, when the first heat transfer sheets 40 affixed to the connection conductors 30 are placed on the mounting portions 51A, the first positioning portions 54 continuously surround the outer periphery of the first heat transfer sheets 40 and the first positioning portions 54 are arranged below the extending portions 34 to as to extend along the outer peripheral edge portions of the extending portions 34.

The protruding length of the first positioning portions 54 from the base main body 51 is set to be equal to the thickness of the first heat transfer sheets 40 when sandwiched by the extending portions 34 and the mounting portions 51A and compressed by the predetermined amount. Here, the term “equal” is used to include both a case in which the protruding length of the first positioning portions 54 from the base main body 51 and the thickness of the first heat transfer sheets 40 when compressed by the predetermined amount are equal and a case in which, even if the two dimensions are not equal, the two dimensions can be regarded as being substantially equal.

That is, even if the first heat transfer sheets 40 are compressed due to being sandwiched from both sides in the top-bottom direction by the extending portions 34 and the mounting portions 51A the first positioning portions 54 come into contact with the entire outer peripheral edge portions of the extending portions 34 in the top-bottom direction and the extending portions 34 are positioned in the top-bottom direction relative to the base main body 51, as illustrated in FIGS. 4 and 5. Thus, the first heat transfer sheets 40 are prevented from being excessively compressed.

As illustrated in FIGS. 4 and 5, the second positioning portions 55 are formed in the shape of rectangular frames that are elongated in the front-rear direction so as to surround the second heat transfer sheets 70 attached to the bottom surfaces of the mounting portions 51A continuously over the entire periphery thereof. The long-side and short-side lengths of the second positioning portions 55 are set to be equal to the long-side and short-side lengths of the first positioning portions 54.

The protruding length of the second positioning portions 55 from the base main body 51 is set to be equal to the thickness of the second heat transfer sheets 70 attached to the bottom surfaces of the mounting portions 51A when the second heat transfer sheets 70 are sandwiched from both sides in the top-bottom direction by the mounting portions 51A and a later-described bracket main body 82 of the bracket 80 and compressed by a predetermined amount. Here, the term “equal” is used to include both a case in which the protruding length of the second positioning portions 55 from the base main body 51 and the thickness of the second heat transfer sheets 70 when compressed by the predetermined amount are equal and a case in which, even if the two dimensions are not equal, the two dimensions can be regarded as being substantially equal.

As illustrated in FIG. 6, the plurality of locking portions 56 are formed so that one locking portion 56 is present at each of the two sides of each first positioning portion 54 in the left-right direction. The two locking portions 56 positioned between the pair of first positioning portions 54 are arranged so as to be displaced from one another in the front-rear direction.

As illustrated in FIG. 5, the locking portions 56 each include an elastic piece 56A that extends upward from the base main body 51, and a locking projection 56B that protrudes from the upper end of the elastic piece 56A toward the inner side, which is the first positioning portion 54 side.

The elastic pieces 56A are elastically displaceable away from the first positioning portions 54. The locking projections 56B are formed so as to protrude to positions above the first positioning portions 54. The bottom surfaces of the locking projections 56B are locking surfaces 56C that face the first positioning portions 54 in the top-bottom direction. The locking surfaces 56C lock, in the top-bottom direction, to the extending portions 34 of the connection conductors 30 arranged above the first positioning portions 54, and thereby hold the connection conductors 30 compressing the first heat transfer sheets 40 by the predetermined amount.

That is, the first heat transfer sheets 40 are compressed by the predetermined amount due to the connection conductors 30 being held by the locking portions 56. Thus, the first heat transfer sheets 40, the extending portions 34, and the mounting portions 51A are brought in close contact with one another in an appropriate manner, and the heat transfer efficiency of the first heat transfer sheets 40 is improved.

As illustrated in FIGS. 3 and 4, the rear stopping portions 58 are formed in the shape of flat plates that extend in the left-right direction so as to continue from the rear portions of the first positioning portions 54.

The rear stopping portions 58 stop the connection conductors 30 from the rear by coming into contact with rear end edges 34A of the extending portions 34 of the connection conductors 30 arranged on the first positioning portions 54.

As illustrated in FIG. 6, the protective wall 59 is formed extending upward from the outer peripheral edge of the base main body 51 so as to extend along the outer peripheral edge of the base main body 51. As illustrated in FIG. 5, the height position of the upper end portion of the protective wall 59 is substantially the same as the height position of the lower end portions of the terminal portions 24 of the relay 20. Thus, the lower end portion of the relay 20, the connection conductors 30, and the first heat transfer sheets 40 are protected from other members by the protective wall 59.

### [Second Heat Transfer Sheets 70]

As illustrated in FIG. 1, the second heat transfer sheets 70 are provided with a configuration similar to that of the first heat transfer sheets 40, and thus description of the configuration of the second heat transfer sheets 70 will be omitted. The second heat transfer sheets 70 transfer heat from the base member 50 to the bracket 80.

The second heat transfer sheets 70 are affixed to the bottom surfaces of the mounting portions 51A of the base member 50 and to the bracket main body 82 of the bracket 80 using unillustrated adhesive layers.

As illustrated in FIGS. 4 and 5, the second heat transfer sheets 70 are in close contact with the mounting portions 51A and the bracket main body 82 of the bracket 80 due to being sandwiched from both sides in the top-bottom direction by the mounting portions 51A and the bracket main body 82 and being compressed by a predetermined amount.

### [Bracket 80]

The bracket 80 is a member to which the base member 50 is attached and which is attached to a battery pack frame, and is formed from a heat conductive metal. As illustrated in FIG. 1, the bracket 80 includes the bracket main body 82, and an outer peripheral plate 84 that extends upward from the outer peripheral edge portion of the bracket main body 82.

The bracket main body 82 is formed in the shape of a rectangular flat plate. As illustrated in FIGS. 4 and 5, the second heat transfer sheets 70 and the second positioning portions 55 of the base member 50 are placed on the top surface of the bracket main body 82.

As illustrated in FIG. 5, the screw fastening portions 86, which form a pair and extend upward, are formed on the two sides of the bracket main body 82 in the left-right direction.

The base member 50 is fixed to the bracket 80 as a result of the pair of screw fastening portions 86 being inserted into the through holes 53 in the base main body 51 of the base member 50 when the base member 50 is arranged on the bracket main body 82 and the screws 87 being fastened to the pair of screw fastening portions 86.

When the base member 50 is fixed to the bracket main body 82, the second positioning portions 55 continuously surround the outer periphery of the second heat transfer sheets 70, and the second heat transfer sheets 70 are compressed by the predetermined amount under the weight of the members attached to the base member 50 from above. Thus, the second heat transfer sheets 70 are brought in close contact with the mounting portions 51A and the bracket main body 82.

The present embodiment has a configuration as described above, and an example of a process for assembling the circuit structure 10 will be described next.

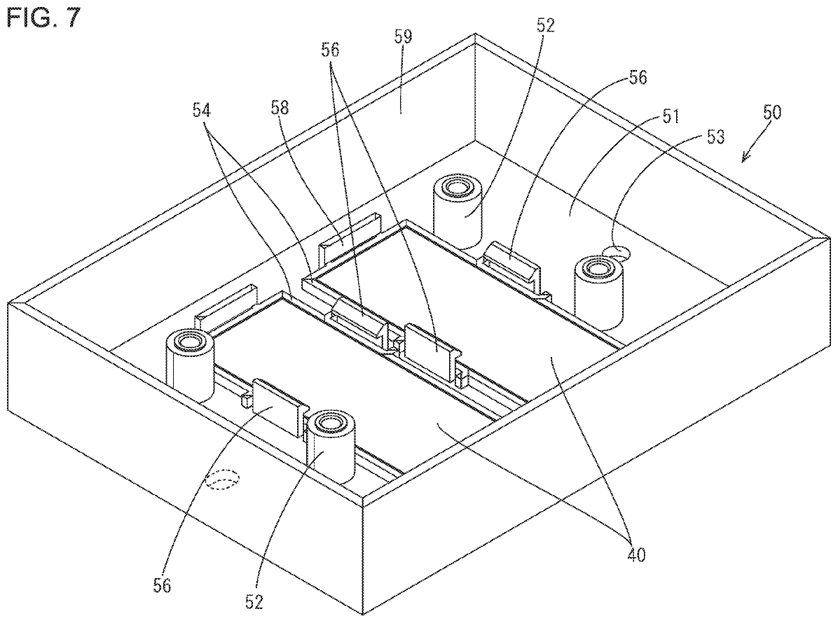

First, the base member 50 is prepared, as illustrated in FIG. 6, and the two first heat transfer sheets 40 are placed on the pair of mounting portions 51A of the base member 50, as illustrated in FIG. 7. Here, the first heat transfer sheets 40 are arranged on the mounting portions 51A without misalignment due to the first heat transfer sheets 40 being arranged inside the first positioning portions 54 using the first positioning portions 54 as guides. Furthermore, in a state in which the first heat transfer sheets 40 have been arranged on the mounting portions 51A, the first heat transfer sheets 40 protrude slightly upward past the first positioning portions 54.

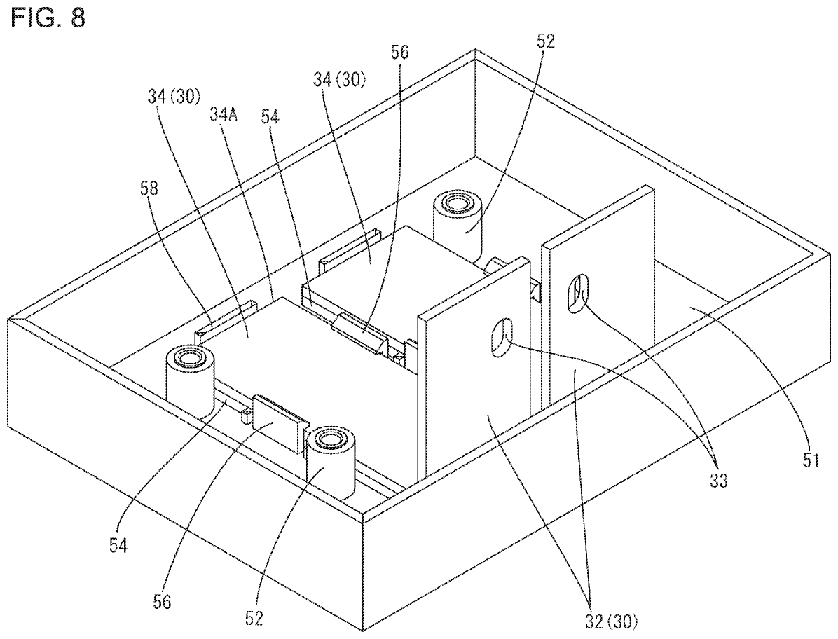

Next, as illustrated in FIG. 8, the connection conductors 30 are attached to the first positioning portions 54 of the base member 50. In this assembly process, the extending portions 34 are arranged on the first positioning portions 54 due to the extending portions 34 of the connection conductors 30 interfering with the locking projections 56B of the locking portions 56 of the base member 50 and the elastic pieces 56A undergoing elastic deformation. When the extending portions 34 are arranged on the first positioning portions 54, the extending portions 34, together with the mounting portions 51A, compress the first heat transfer sheets 40 from both sides in the top-bottom direction by the predetermined amount, and the first heat transfer sheets 40 are brought in close contact with the extending portions 34 and the mounting portions 51A. Furthermore, when the extending portions 34 are arranged on the first positioning portions 54, the interference between the extending portions 34 and the locking projections 56B is released, and the elastic pieces 56A elastically return to their original positions. Then, the extending portions 34 and the locking surfaces 56C of the locking projections 56B of the locking portions 56 lock to one another in the top-bottom direction, and the extending portions 34 are held in a state in which the extending portions 34, together with the mounting portions 51A, compress the first heat transfer sheets 40 by the predetermined amount.

Next, the relay 20 is fixed to the base member 50 as a result of the relay 20 being attached to the base member 50 so that the fixing portions 26 of the relay 20 are placed on the bolt fastening portions 52 of the base member 50, and the fixing portions 26 being fastened by bolts to the bolt fastening portions 52.

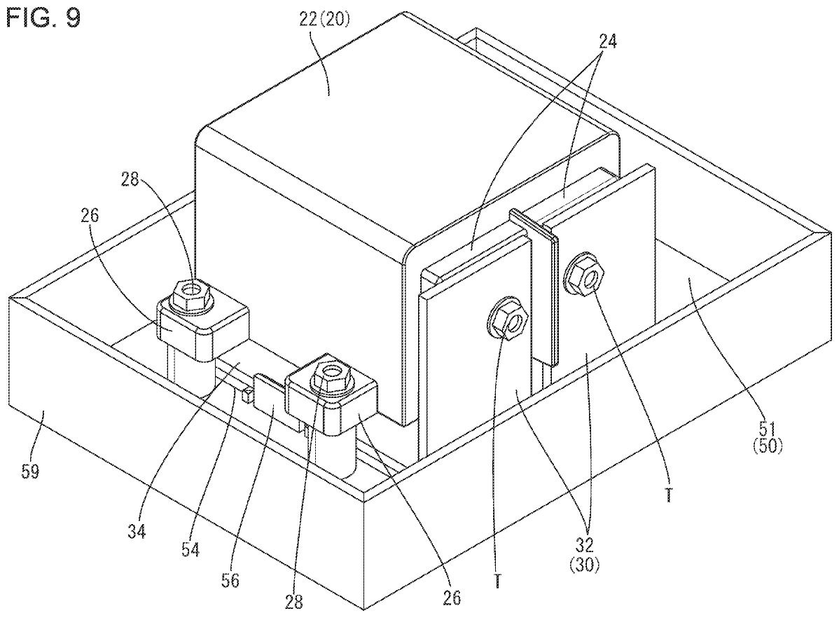

Next, the bolt insertion holes 33 in the member connection portions 32 of the connection conductors 30 and the bolt holes 25 in the terminal portions 24 of the relay 20 are positioned relative to one another, and the shaft portions T1 of the bolts T, which are fastening members, are fastened to the bolt holes 25, as illustrated in FIG. 9. Thus, the terminal portions 24 of the relay 20 and the member connection portions 32 of the connection conductors 30 are connected in a heat-transferable state.

Here, when the extending portions 34 are pressed downward as the bolt insertion holes 33 and the bolt holes 25 are positioned relative to one another, the extending portions 34 are positioned relative to the base main body 51 in the top-bottom direction due to the extending portions 34 and the first positioning portions 54 coming into contact with one another in the top-bottom direction, as illustrated in FIGS. 4 and 5. Thus, the first heat transfer sheets 40 are prevented from being excessively compressed. Note that in the present embodiment, the bolts T are fastened to the bolt holes 25 in a state in which the extending portions 34 are pressed downward, as illustrated in FIGS. 4 and 5. Accordingly, clearances are formed between the extending portions 34 and the locking surfaces 56C of the locking portions 56.

Next, the second heat transfer sheets 70 are affixed to the bottom surfaces of the mounting portions 51A of the base member 50. Here, the second heat transfer sheets 70 are arranged on the mounting portions 51A without misalignment due to the second positioning portions 55 guiding the second heat transfer sheets 70.

Next, the base member 50 is fixed to the bracket 80 as a result of the screw fastening portions 86 of the bracket 80 being inserted into the through holes 53 in the base member 50 and the screws 87 being fastened to the screw fastening portions 86. Here, when the base member 50 is fixed to the bracket 80, the second heat transfer sheets 70 are compressed by the predetermined amount under the weight of the members attached to the base member 50 from above, and the mounting portions 51A and the bracket main body 82 are brought in close contact, as illustrated in FIGS. 4 and 5.

Furthermore, in the case in which the base member 50 is fixed to the bracket 80 as well, the base main body 51 is positioned relative to the bracket main body 82 in the top-bottom direction due to the second positioning portions 55 and the bracket main body 82 coming into contact with one another in the top-bottom direction. Thus, the second heat transfer sheets 70 are prevented from being excessively compressed.

The circuit structure 10 is produced in such a manner.

Subsequently, the actions and effects of the circuit structure 10 will be described.

For example, in a case in which the extending portions 34 are pressed downward due to the manufacturing tolerance of the relay 20, the connection conductors 30, and the base member 50 or the assembly tolerance when the members are attached to each other, the first heat transfer sheets 40 may be excessively compressed by the connection conductors 30. If the first heat transfer sheets 40 are excessively compressed by the connection conductors 30, there is a concern that the members may be damaged by high stress applied to portions where the members are connected to one another due to the resilience of the first heat transfer sheets 40.

Thus, the present inventor, etc., conducted diligent investigations to solve the above-described problem and arrived at the configuration of the present embodiment. That is, the present embodiment is a circuit structure 10 including: a relay 20 (heat-generating member); at least one connection conductor 30; at least one insulative first heat transfer sheet (heat transfer member) 40; and an insulative base member 50. The relay 20 generates heat as a result of being energized, the connection conductor 30 is connected to the relay 20 in a heat-transferable state, the first heat transfer sheet 40 is formed in the shape of a heat-transferable sheet, the base member 50 includes a base main body 51 and a first positioning portion (positioning portion) 54, the base main body 51, together with the connection conductor 30, sandwiches the first heat transfer sheet 40, and the first positioning portion 54 is formed so as to protrude from the base main body 51, and positions the connection conductor 30 relative to the base main body 51 as a result of coming into contact with the connection conductor 30.

As illustrated in FIGS. 4 and 5, due to the connection conductor 30 coming into contact with the first positioning portion 54, the gap between the connection conductor 30 and the base member 50 can be prevented from becoming less than or equal to a predetermined dimension. That is, the connection conductor 30 and the base main body 51 can be brought in contact with the first heat transfer sheet 40 while preventing the first heat transfer sheet 40 sandwiched between the base main body 51 and the connection conductor 30 from being excessively compressed.

Thus, the efficiency with which the relay 20 is cooled can be improved due to the heat from the relay 20 being transferred from the relay 20 to the connection conductor 30 and from the connection conductor 30 to the base member 50 via the first heat transfer sheet 40. Furthermore, since the first heat transfer sheet 40 is not excessively compressed by the connection conductor 30, stress originating from the resilience of the first heat transfer sheet 40 can be prevented from being applied to the relay 20, the connection conductor 30, and the base member 50. Thus, the relay 20, the connection conductor 30, and the base member 50 can be prevented from being damaged.

Furthermore, the first positioning portion 54 is arranged in the outer periphery of the first heat transfer sheet 40, and thus the first positioning portion 54 can also be used as a guide for attaching the first heat transfer sheet 40 to the base main body 51.

Furthermore, the connection conductor 30 includes a member connection portion 32 and an extending portion 34, the member connection portion 32 can be connected to the relay 20, the extending portion 34 extends in the shape of a plate from the member connection portion 32, and the first positioning portion 54 is formed so as to be capable of coming into contact with the entire outer peripheral edge portion of the extending portion 34.

Since the first positioning portion 54 comes into contact with the entire outer peripheral edge portion of the extending portion 34, the connection conductor 30 can be more reliably positioned by the first positioning portion 54 compared to a case in which the first positioning portion comes into contact with one end of the extending portion, for example. Thus, the first heat transfer sheet 40 can be reliably prevented from being excessively compressed by the connection conductor 30.

The first heat transfer sheet 40 is formed so as to be elastically compressible, and the protruding length of the first positioning portion 54 from the base main body 51 is set to be equal to the thickness of the first heat transfer sheet 40 when compressed by a predetermined amount.

The first heat transfer sheet 40 can be prevented from being excessively compressed by the predetermined amount or more when the connection conductor 30 is pressed toward the base main body 51.

The base member 50 further includes a plurality of locking portions 56, and the plurality of locking portions 56 lock, from the side opposite from the first heat transfer sheet 40, the connection conductor 30 compressing the first heat transfer sheet 40.

Due to the locking portions 56 locking, from the side opposite from the first heat transfer sheet 40, the connection conductor 30 compressing the first heat transfer sheet 40, the first heat transfer sheet 40 can be kept in a state in which the first heat transfer sheet 40 is compressed by the predetermined amount by the connection conductor 30 and the base main body 51. Thus, a state in which the first heat transfer sheet 40 is brought in close contact with the connection conductor 30 and the base main body 51 in an appropriate manner can be maintained, and the heat transfer efficiency of the first heat transfer sheet 40 can be improved.

The relay 20 and the connection conductor 30 are connected in a heat-transferable state by a bolt (fastening member) T, the connection conductor 30 has a bolt insertion hole (insertion hole) 33 into which a shaft portion T1 of the bolt T is inserted, and the bolt insertion hole 33 is formed so as to be elongated in the direction in which the connection conductor 30 comes into contact with the first positioning portion 54, as illustrated in FIG. 4.

The shaft portion T1 of the bolt T can move inside the bolt insertion hole 33 in the direction in which the connection conductor 30 comes into contact with the first positioning portion 54. That is, the assembly tolerance occurring between the relay 20, the connection conductor 30, and the first positioning portion 54 can be absorbed by the bolt insertion hole 33. Thus, stress originating from the assembly tolerance can be prevented from being applied to the relay 20, the connection conductor 30, and the base member 50. Accordingly, the relay 20, the connection conductor 30, and the base member 50 can be prevented from being damaged.

A metal bracket 80 and at least one second heat transfer sheet 70 are further included, the base member 50 is fixed to the bracket 80, the second heat transfer sheet 70 is formed in the shape of a heat-transferable sheet and sandwiched between the base main body 51 and the bracket 80, the base main body 51 further includes a second positioning portion 55, and the second positioning portion 55 is formed so as to protrude toward the bracket 80 side from the base main body 51, and positions the bracket 80 relative to the base main body 51 as a result of coming into contact with the bracket 80.

The heat from the relay 20 transferred to the base member 50 can be released to the bracket 80 via the second heat transfer sheet 70. Furthermore, the second heat transfer sheet 70 is similar to the first heat transfer sheet 40 in that the gap between the bracket 80 and the base main body 51 can be prevented from becoming less than or equal to a predetermined dimension due to the bracket 80 coming into contact with the second positioning portion 55 as illustrated in FIGS. 4 and 5. Thus, the second heat transfer sheet 70 can be prevented from being excessively compressed. That is, since the second heat transfer sheet 70 is not excessively compressed by the bracket 80, stress originating from the resilience of the second heat transfer sheet 70 can be prevented from being applied to the bracket 80 and the base member 50, and the bracket 80 and the base member 50 can be prevented from being damaged.

### Other Embodiments

(1) In the above-described embodiment, a configuration is adopted in which the base member 50 is fixed to a battery pack frame via the second heat transfer sheets 70 and the bracket 80. However, there is no limitation to this, and a configuration in which the base member is directly fixed to a battery pack frame may be adopted.

(2) In the above-described embodiment, the relay 20 is described as one example of a heat-generating component. However, there is no limitation to this, and the heat-generating component may be any electronic component such as a semiconductor relay, a capacitor, or a diode.

(3) In the above-described embodiment, a configuration is adopted in which the first heat transfer sheets 40 and the second heat transfer sheets 70 are affixed to the base member 50, the connection conductors 30, and the bracket 80 using adhesive layers. However, there is no limitation to this, and a configuration may be adopted in which the heat transfer sheets are not affixed to the base member 50, the connection conductors 30, or the bracket 80 due to being held inside the first positioning portions and second positioning portions.

(4) In the above-described embodiment, a configuration is adopted in which the extending portions 34 of the connection conductors 30 are arranged below the relay 20. However, there is no limitation to this, and a configuration may be adopted in which the extending portions extend in a direction away from the relay.

(5) In the above-described embodiment, a configuration is adopted in which the first positioning portions 54 and the second positioning portions 55 are formed so as to continuously surround the outer periphery of the first heat transfer sheets 40 or the second heat transfer sheets 70, and the first positioning portions 54 and the second positioning portions 65 come into contact with the outer peripheral edge portions of the extending portions 34 or the bracket main body 82 continuously over the entire periphery thereof. However, there is no limitation to this, and a configuration may be adopted in which the first positioning portions and the second positioning portions are formed intermittently in the outer periphery of the first heat transfer sheets or second heat transfer sheets, and the first positioning portions and the second positioning portions intermittently come into contact with the outer peripheral edge portions of the extending portions or the bracket main body.

### LIST OF REFERENCE NUMERALS

10: Circuit structure
20: Relay (one example of “heat-generating component”)
22: Relay main body
24: Terminal portion
25: Bolt hole
26: Fixing portion
27: Insertion hole
28: Bolt
30: Connection conductor
32: Member connection portion
33: Bolt insertion hole (one example of “insertion hole”)
34: Extending portion
34A: Rear end edge
40: First heat transfer sheet (one example of “heat transfer member”)
50: Base member
51: Base main body
51A: Mounting portion
52: Bolt fastening portion
53: Through hole
53A: Through hole
54: First positioning portion (one example of “positioning portion”)
55: Second positioning portion
56: Locking portion
56A: Elastic piece
56B: Locking projection
56C: Locking surface
58: Rear stopping portion
59: Protective wall
70: Second heat transfer sheet (one example of “second heat transfer member”)
80: Bracket
82: Bracket main body
84: Outer peripheral plate
86: Screw fastening portion
87: Screw
T1: Shaft portion
T: Bolt (one example of “fastening member”)

1. A circuit structure comprising: a heat-generating member; at least one connection conductor; at least one insulative heat transfer member; and an insulative base member,
wherein the heat-generating member generates heat as a result of being energized,
the connection conductor is connected to the heat-generating member in a heat-transferable state,
the heat transfer member is a heat-transferable sheet,
the base member includes a base main body and a positioning portion,
the base main body, together with the connection conductor, sandwiches the heat transfer member, and
the positioning portion protrudes from the base main body, and positions the connection conductor relative to the base main body as a result of coming into contact with the connection conductor.

2. The circuit structure according to claim 1, wherein the positioning portion is arranged around the outer periphery of the heat transfer member.

3. The circuit structure according to claim 2,
wherein the connection conductor includes a member connection portion and an extending portion,
the member connection portion is configured to be connected to the heat-generating member,
the extending portion extends as a plate from the member connection portion, and
the positioning portion is configured to come into contact with the entire outer peripheral edge portion of the extending portion.

4. The circuit structure according to claim 1,
wherein the heat transfer member is formed so as to be elastically compressible, and
a protruding length of the positioning portion from the base main body is equal to the thickness of the heat transfer member when compressed by a predetermined amount.

5. The circuit structure according to claim 4,
wherein the base member further includes a plurality of locking portions, and
the plurality of locking portions lock, from the side opposite from the heat transfer member, the connection conductor compressing the heat transfer member.

6. The circuit structure according to claim 1,
wherein the heat-generating member and the connection conductor are connected in a heat-transferable state by a fastening member,
the connection conductor has an insertion hole into which a shaft portion of the fastening member is inserted, and
the insertion hole is elongated in the direction in which the connection conductor comes into contact with the positioning portion.

7. The circuit structure according to claim 1, further comprising:
a metal bracket; and at least one second heat transfer member,
wherein the base member is fixed to the bracket,
the second heat transfer member is a heat-transferable sheet and sandwiched between the base main body and the bracket,
the base main body further includes a second positioning portion, and
the second positioning portion protrudes toward the bracket side from the base main body, and positions the bracket relative to the base main body as a result of coming into contact with the bracket.
